(19) United States
(12) Patent Application Publication
(10) Pub. No.: US 2024/0268100 A1
(43) Pub. Date: Aug. 8, 2024

(54) SEMICONDUCTOR STRUCTURE AND METHOD FOR FORMING THE SAME

(71) Applicant: Winbond Electronics Corp., Taichung City (TW)

(72) Inventor: Huang-Nan CHEN, Taichung City (TW)

(21) Appl. No.: 18/410,162

(22) Filed: Jan. 11, 2024

(30) Foreign Application Priority Data
Feb. 7, 2023 (TW) 112104230

(51) Int. Cl. H10B 12/00

(52) U.S. Cl. CPC H10B 12/482; H10B 12/03; H10B 12/315; H10B 12/488

(57) ABSTRACT

A semiconductor structure is provided. The structure includes a substrate, first and second word lines, first and second storage capacitor contacts, a bit line, an insulating layer, and an inverted U-shaped isolation layer. The substrate has first and second active areas adjacent to each other, and the first and second word lines are formed in the substrate. The first and second storage capacitor contacts are respectively coupled to the first and second active areas, and disposed on the same side of the bit line. The bit line spans the first and second word lines. The insulating layer is formed between the first and second storage capacitor contacts. The inverted U-shaped isolation layer is formed in the insulating layer and spans the bit line.

### CROSS REFERENCE TO RELATED APPLICATIONS

This application claims priority of Taiwan Patent Application No. 112104230 filed on Feb. 7, 2023, and entitled “SEMICONDUCTOR STRUCTURE AND METHOD FOR FORMING THE SAME”, the entirety of which is incorporated by reference herein.

### BACKGROUND OF THE INVENTION

### Field of the Invention

The invention relates to semiconductor technology, and in particular to semiconductor structures for improving electrical isolation between adjacent contacts and methods for forming the same.

### Description of the Related Art

With the increasing demand for miniaturization, how to increase the density of semiconductor elements has become a critical issue. In the manufacture of contacts (e.g., storage capacitor contacts or storage node contacts) of semiconductor memory devices, spacer liners are formed on the sidewalls of the contact materials, and an insulating layer (e.g., silicon oxide) fills the space between the opposite spacer liners of two adjacent contacts to function as an electrical isolation layer between adjacent contacts. With the miniaturization of semiconductor devices, however, the pitch of the contacts has become smaller, and unexpected voids are prone to occur in the insulating layer between the contacts, meaning that the spacer liner is prone to damage. As a result, this easily causes the bridging of adjacent contacts, leading to electrical short circuits.

Accordingly, there is need for a novel method of manufacturing a contact structure of a semiconductor memory device that is capable of addressing or improving upon the aforementioned problems.

### BRIEF SUMMARY OF THE INVENTION

Embodiments of the present disclosure provide a semiconductor structure and a manufacturing method thereof, which can prevent electrical short circuits caused by the bridging of adjacent storage capacitor contacts during the manufacturing process.

In some embodiments, a semiconductor structure is provided. The semiconductor structure includes a substrate, a first word line and a second word line, a bit line, a first storage capacitor contact and a second storage capacitor contact, an insulating layer, and an inverted U-shaped isolation layer. The substrate has a first active area and an adjacent second active area. The first word line and the second word line are disposed in the substrate, and the bit line spans the first word line and the second word line. The first storage capacitor contact and the second storage capacitor contact are respectively formed on the first word line and the second word line to be respectively coupled to the first active area and the second active area. The first storage capacitor contact and the second storage capacitor contact are disposed on the same side of the bit line. The insulating layer is disposed between the first storage capacitor contact and the second storage capacitor contact, and the inverted U-shaped insulating layer is disposed in the insulating layer and spans the bit line.

In some embodiments, a method for manufacturing a semiconductor structure is provided. The method includes forming a first word line and a second word line that extend along a first direction and in a substrate. The substrate has a first active area and an adjacent second active area. The method also includes forming an insulating layer on the substrate and patterning the insulating layer to form a first opening, a second opening, and a third opening between the first opening and the second opening. The first opening and the second opening respectively correspond to the first active area and the second active area, and the third opening extends between the first word line and the second word line along the first direction, as viewed from a top-view perspective. The method further includes forming an isolation layer in the third opening, forming a first storage capacitor contact in the first opening and forming a second storage capacitor contact in the second opening.

According to some embodiments of the present disclosure, an inverted U-shaped isolation layer is additionally formed in the insulating layer between the first storage capacitor contact and the second storage capacitor contact. Therefore, it can improve the electrical isolation between the first storage capacitor contact and the second storage capacitor contact without affecting the bit line configuration. Moreover, due to the existence of the inverted U-shaped isolation layer, the thickness of the spacer between the insulating layer and the storage capacitor contact can be reduced, and even the spacer can be omitted. As a result, the volume of the storage capacitor contact can be increased, thereby reducing the contact resistance of the storage capacitor contact. Moreover, the parasitic capacitance between the first storage capacitor contact and the second storage capacitor contact can also be reduced.

### BRIEF DESCRIPTION OF THE DRAWINGS

FIG. 1A is a top view of a semiconductor structure according to an embodiment of the present disclosure.

FIG. 1B is a perspective view of the region R1 shown in FIG. 1A.

FIGS. 2A-2I are cross-sectional views of various fabrication stages of the semiconductor structure according to some embodiments of the present disclosure, in which the cross-sectional views shown in FIGS. 2A-2I correspond to cross-sections along line A-A′ shown in FIGS. 1A and 1B.

FIG. 2I-1 is a cross-sectional view of an intermediate fabrication stage of a semiconductor structure according to some embodiments of the present disclosure.

FIGS. 3A-3E are cross-sectional views of various fabrication stages of the semiconductor structure according to some embodiments of the present disclosure, in which the cross-sectional views shown in FIGS. 3A-3E correspond to cross-sections along line A-A′ shown in FIGS. 1A and 1B.

FIG. 4 is a perspective view of an inverted U-shaped isolation layer according to some embodiments of the present disclosure.

### DETAILED DESCRIPTION OF THE INVENTION

The making and using of the embodiments of the present disclosure are discussed in detail below. However, it should be noted that the embodiments provide many applicable inventive concepts that can be embodied in a variety of specific methods. The specific embodiments discussed are merely illustrative of specific methods to make and use the embodiments, and do not limit the scope of the disclosure. In addition, the present disclosure may repeat reference numbers and/or letters in the various embodiments. This repetition is for the purpose of simplicity and clarity, and does not imply any relationship between the different embodiments and/or configurations discussed.

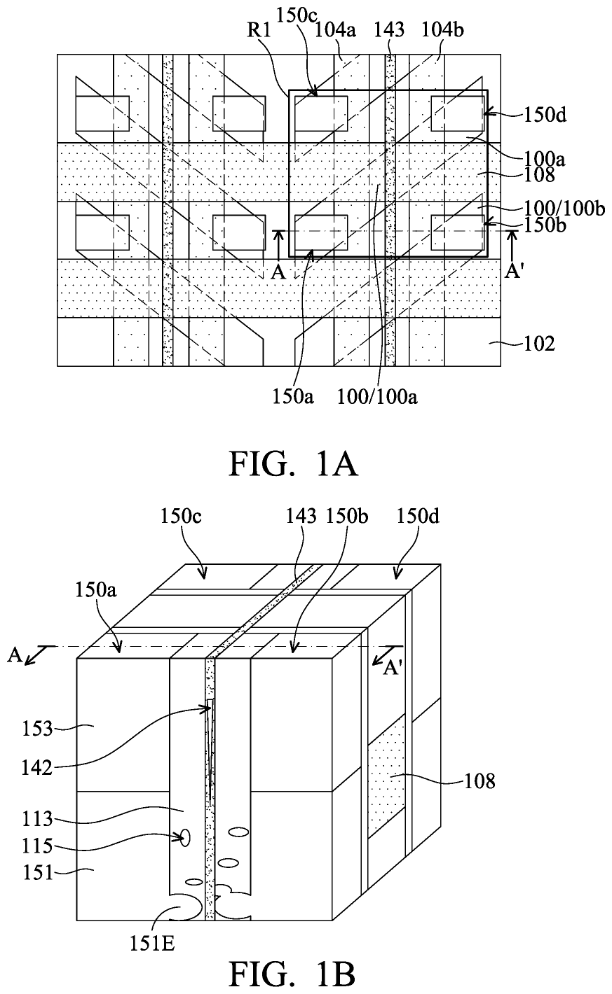

Refer to FIGS. 1A and 1B, in which FIG. 1A shows a schematic top view of a memory device having a semiconductor structure according to an embodiment of the present disclosure, and FIG. 1B is a perspective view of the region R1 shown in FIG. 1A. For clarity, some features shown in FIG. 1A are not depicted in FIG. 1B, while some features shown in FIG. 1B are not depicted in FIG. 1A. In this embodiment, the memory device is, for example, a dynamic random-access memory (DRAM).

In some embodiments, the semiconductor structure includes a substrate 100 and island-shaped active areas defined by isolation regions 102 (e.g., shallow trench isolation regions). Herein, only two active areas (a first active area 100a and an adjacent second active area 100b) in the region R1 are labeled. The substrate 100 can be a silicon semiconductor substrate, a silicon-on-insulator (SOI) semiconductor substrate, or another suitable semiconductor substrate (for example, a gallium arsenide semiconductor substrate, a gallium nitride semiconductor substrate, or a silicon germanium semiconductor substrate). In some embodiments, substrate 100 is a silicon semiconductor substrate.

In some embodiments, the semiconductor structure further includes word lines (not shown in FIG. 1B), and each word line extends along the first direction and pass through the corresponding island-shaped active area. In this embodiment, the extending direction of the word line intersects with the extending direction of the active area to form a first inclined angle (that is, this angle is not equal to 90 degrees), but the embodiment is not limited thereto. Herein, only two word lines (a first word line 104a and an adjacent second word line 104b) in the region R1 are labeled. In some embodiments, the word line (which is sometimes referred to as a gate line) is buried in the substrate 100, so it can also be referred to as a buried word line (BWL). As viewed from a top-view perspective, the first word line 104a and the second word line 104b each pass through the first active area 100a and the second active area 100b.

In some embodiments, the semiconductor structure further includes bit lines, and each bit line extends along a second direction (e.g., which is perpendicular to the first direction) and passes through the corresponding island-shaped active area at a second inclined angle. In FIG. 1A, only one bit line 108 in region R1 is labeled. As viewed from a top-view perspective, the bit line 108 spans the first word line 104a and the second word line 104b, and obliquely spans the first active area 100a.

In some embodiments, the semiconductor structure further includes storage capacitor contacts. Each storage capacitor contact includes a single layer or a multi-layer conductive structure. For example, the storage capacitor contact may have a lower conductive structure 151 and an upper conductive structure 153. The lower conductive structure 151 may include semiconductor material, such as polysilicon. The upper conductive structure 153 may include metal, such as tungsten. As viewed from a top-view perspective, the storage capacitor contact is disposed adjacent to the corresponding bit line and overlaps the corresponding active area and the corresponding word line. The storage capacitor contact is employed to electrically couple the corresponding active area to a corresponding storage node (not shown). In this embodiment, as viewed from a top-view perspective of the region R1, the first storage capacitor contact 150a and the second storage capacitor contact 150b partially overlap the first word line 104a and the second word line 104b, respectively. Moreover, the third storage capacitor contact 150c and the fourth The storage capacitor contact 150d partially overlap with the first word line 104a and the second word line 104b, respectively. The first storage capacitor contact 150a and the second storage capacitor contact 150b are disposed on the same side of the bit line 108, while the third storage capacitor contact 150c and the fourth storage capacitor contact 150d are disposed on the other side of the bit line 108.

In some embodiments, the semiconductor structure further includes an insulating layer 113 (not shown in FIG. 1A) formed between two adjacent storage capacitor contacts on the same side of the bit line 108, to electrically isolate the two adjacent storage capacitor contacts. For example, the insulating layer 113 is disposed between the first storage capacitor contact 150a and the second storage capacitor contact 150b, and between the third storage capacitor contact 150c and the fourth storage capacitor contact 150d. The insulating layer 113 can be a single layer or a multi-layer structure. For example, the insulating layer 113 is a multi-layer insulating structure that includes silicon oxide (e.g., spin-on glass (SOG)). As the aspect ratio gets higher, voids 115 are prone to be formed at the bottom of the filled spin-on-glass (SOG). Therefore, if the void 115 is formed near the edge of the insulating layer 113 during formation of the lower conductive structure 151 of the storage capacitor contact on two opposite sides of the insulating layer 113, the material of the lower conductive structure 151 (e.g., polysilicon) is prone to be filled into the void 115. As a result, the lower conductive structure 151 has an extension portion 151E extending into the insulating layer 113, as shown in FIG. 1B.

In some embodiments, the semiconductor structure further includes additional isolation layers 143 disposed in the corresponding insulating layers 113, respectively. As viewed from a top-view perspective, each isolation layer 143 extends along the first direction (i.e., the extending direction of the word lines), and is disposed between two adjacent word lines. In other words, the isolation layer 143 obliquely spans the first active area 100a and the second active area 100b and spans the bit line 108. In some embodiments, in order to prevent the lower conductive structure 151 extending into the insulating layer 113 from being bridged and short-circuited, the isolation layer 143 extends from the upper surface of the insulating layer 113 to the lower surface of the insulating layer 113. As a result, a block wall is formed to obstruct the coupling between the extended portions 151E of the lower conductive structure 151, thereby ensuring electrical isolation between storage capacitor contacts. In some embodiments, the isolation layer 143 includes silicon nitride or another suitable insulating material.

Refer to FIG. 4, in some embodiments, the isolation layer 143 is inverted U-shaped, so it is also referred to as an inverted U-shaped isolation layer 143 herein. The inverted U-shaped isolation layer 143 includes a horizontal portion 143a and two extending portions 143b extending from two ends of the horizontal portion 143a in a direction that is toward the substrate 100 (e.g., vertical direction). Moreover, the inverted U-shaped isolation layer 143 spans the bit line 108. For example, the horizontal portion 143a of the inverted U-shaped isolation layer 143 covers the upper surface of the bit line 108, and the two extending portions 143b of the inverted U-shaped isolation layer 143 respectively cover two opposite sidewall surfaces of the bit line 108. As a result, the electrical isolation between storage capacitor contacts can be effectively improved without affecting the bit line configuration (e.g., without cutting the bit line).

In some embodiments, the horizontal portion 143a of the inverted U-shaped isolation layer 143 has an air gap 142. The air gap 142 extends along the first direction and spans the bit line 108. The air gap 142 can reduce the dielectric constant of the horizontal portion 143a of the inverted U-shaped isolation layer 143, thereby reducing the parasitic capacitance between the first storage capacitor contact 150a and the second storage capacitor contact 150b and/or between the third storage capacitor contact 150c and the fourth storage capacitor contact 150d.

In some embodiments that are not shown, there is an insulating spacer disposed between the insulating layer 113 and the adjacent storage capacitor contact. The insulating spacer may serve as an electrical isolation layer and/or a diffusion barrier layer. For example, the insulating spacer can be made of silicon nitride. With the inverted U-shaped isolation layer 143, even if the insulating spacer is thinned or even damaged due to the subsequent etching process, the inverted U-shaped isolation layer 143 can still prevent adjacent storage capacitor contacts from bridging. Therefore, in some embodiments, such an insulating spacer can be omitted between the insulating layer 113 and the storage capacitor contact. As a result, the volume of the storage capacitor contact can be increased, thereby reducing the contact resistance of the storage capacitor contact.

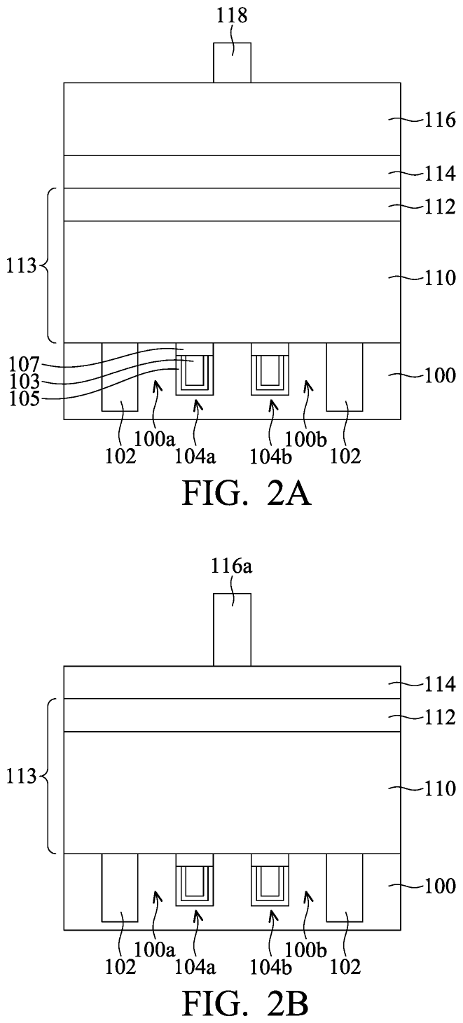

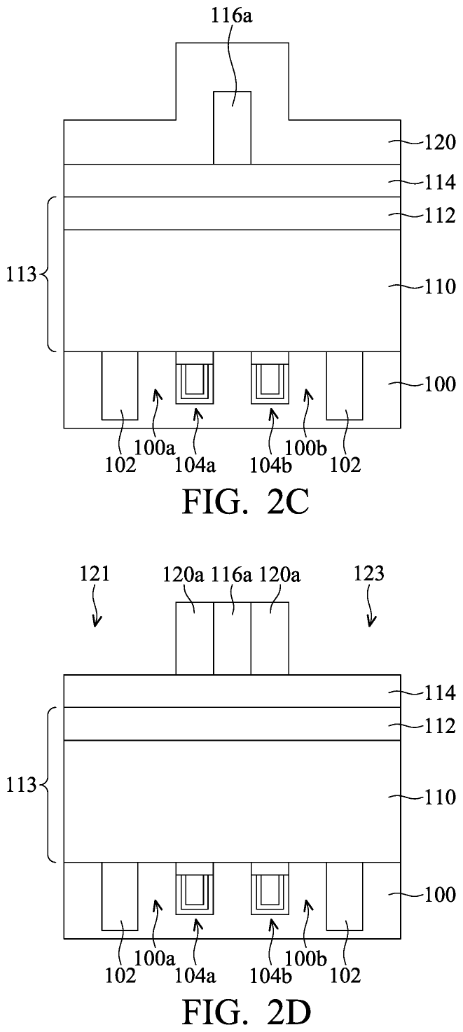

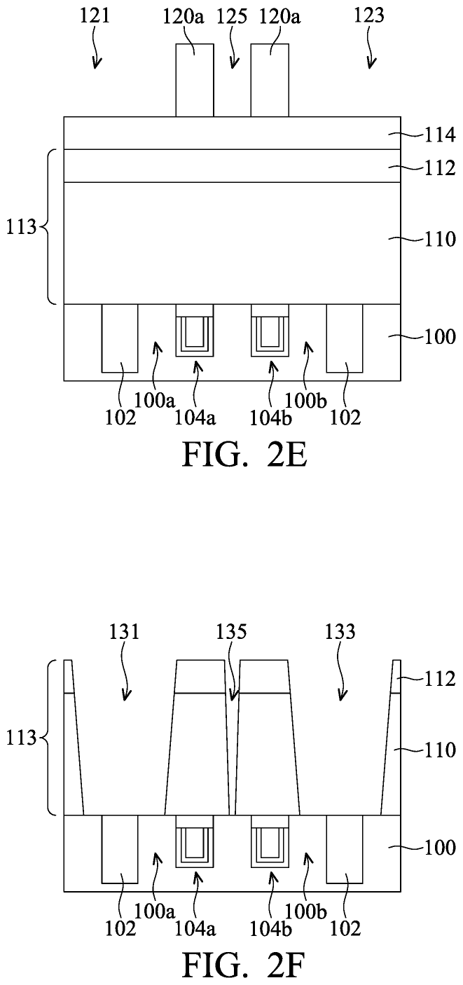

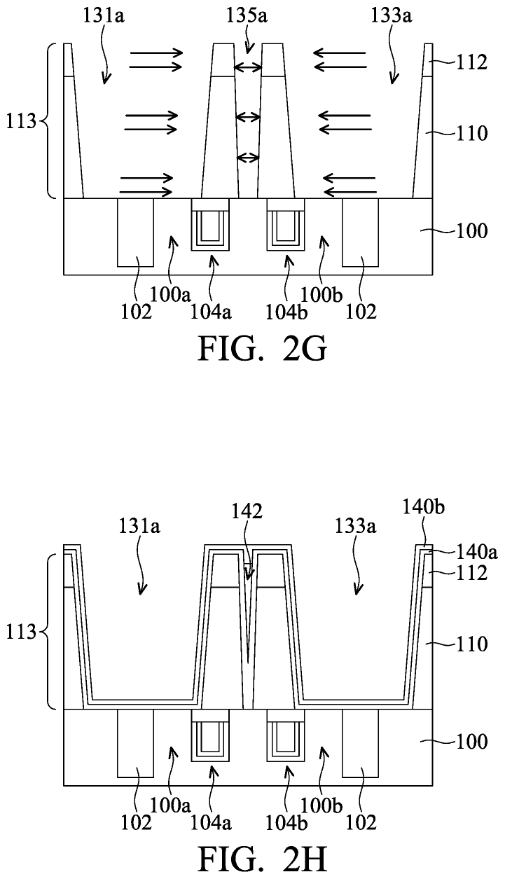

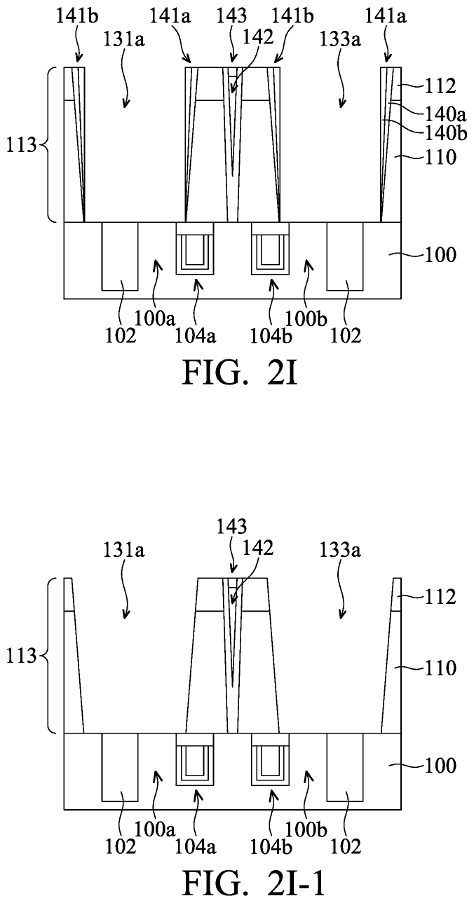

The following provides the manufacturing method of the semiconductor structure according to some embodiments of the present disclosure, which can form the semiconductor structure shown in FIG. 1A and FIG. 1B. Therefore, similar or the same descriptions will not be repeated. As shown in FIG. 2A, a first word line 104a and a second word line 104b are formed in the substrate 100. Each of the first word line 104a and the second word line 104b includes a gate electrode 103, a gate dielectric layer 105 surrounding the sidewall and bottom of the gate electrode 103, and a capping layer 107 on the top of the gate electrode 103.

Next, an insulating layer 113, a mask layer 114, a sacrificial layer 116 and a photoresist pattern layer 118 are successively formed on the substrate 100. It can be understood that, before the insulating layer 113 is formed, the bit line 108 (as shown in FIGS. 1A and 1B) has been formed above the substrate 100, so that the insulating layer 113 spans the bit line 108.

In this embodiment, the insulating layer 113 includes a first dielectric layer 110 and a second dielectric layer 112. The material of the insulating layer 113 includes silicon oxide, a low-k dielectric material or a combination thereof. For example, the first dielectric layer 110 may include spin-on-glass (SOG), and the second dielectric layer 112 may include tetraethylorthosilicate (TEOS) oxide.

In this embodiment, the hard mask layer 114 includes an amorphous carbon layer, polysilicon, or another suitable mask material. The sacrificial layer 116 includes silicon oxide.

In some embodiments, the photoresist pattern layer 118 has a mandrel pattern and can be formed via a lithography process. As viewed from a top-view perspective, the mandrel pattern extends between the adjacent first word line 104 and the second word line 104b along the first direction to define the region where the subsequent isolation layer is to be formed.

Next, refer to FIG. 2B, the sacrificial layer 116 is patterned to transfer the mandrel pattern of the photoresist pattern layer 118 into the underlying sacrificial layer 116. As a result, a sacrificial mandrel layer 116a is formed on the hard mask layer 114.

Next, refer to FIG. 2C, a spacer material liner 120 is formed on the hard mask layer 114 to conformally cover the surface of the sacrificial mandrel layer 116a. In some embodiments, the material of the spacer material liner 120 includes silicon oxide. The insulating layer 113, the hard mask layer 114, the sacrificial layer 116, and the spacer material liner 120 can be formed via a suitable deposition process, such as a chemical vapor deposition (CVD) process, an atomic layer deposition (ALD) process, a spin coating process, or another suitable deposition process.

Next, refer to FIG. 2D, the horizontally extending portion of the spacer material liner 120 is removed to leave spacer layers 120a on the hard mask layer 114 and cover the sidewall surfaces of the sacrificial mandrel layer 116a. The formed spacer layers 120a have a first opening pattern 121 and a second opening pattern 123 respectively formed on two opposite sides of the sacrificial mandrel layer 116a. Moreover, the first opening pattern 121 and the second opening pattern 123 are separated from the sacrificial mandrel layer 116a by the corresponding spacer layer 120a. In some embodiments, the first opening pattern 121 and the second opening pattern 123 define a region where the subsequent storage capacitor contact is to be formed.

Next, refer to FIG. 2E, the sacrificial mandrel layer 116a is removed. In one embodiment, the sacrificial mandrel layer 116a is removed by using the spacer layer 120a as an etch mask and using the hard mask layer 114 as an etch stop layer, to form a third opening pattern 125 in the spacer layer 120a. The third opening pattern 125 defines a region where the isolation layer 143 is to be formed.

Next, refer to FIG. 2F, the insulating layer 113 is patterned to form a first opening 131, a second opening 133 and a third opening 135 between the first opening 131 and the second opening 133 in the insulating layer 113. In some embodiments, one or more etching processes are performed on the mask layer 114, the second dielectric layer 112, and the first dielectric layer 110 in sequence by using the spacer layer 120a as an etch mask, so that the first opening pattern 121, the second opening pattern 123 and the third opening pattern 125 are transferred into the mask layer 114 and the insulating layer 113. Afterwards, the mask layer 114 is removed. In some embodiments, the first opening 131 and the second opening 133 correspond to the first active area 100a and the second active area 100b, respectively. Moreover, as viewed from a top-view perspective, the third opening 135 extends between the first word line 104a and the second word line 104b along the first direction. As a result, the first opening 131 and the second opening 133 respectively form regions where storage capacitor contacts are to be disposed. Moreover, the third opening 135 forms the region where the isolation layer is to be disposed. The width of the third opening 135 is smaller than the width of the first opening 131 and the width of the second opening 133.

Optionally, as shown in FIG. 2G, after the first opening 131, the second opening 133 and the third opening 135 are formed, the first opening 131, the second opening 133 and the third opening 135 may be widened laterally. As a result, a widened first opening 131a, a widened second opening 133a, and a widened third opening 135a are formed in the insulating layer 113. The following embodiments will be described by taking the formed widened first opening 131a, the formed widened second opening 133a, and the formed widened third opening 135a in the insulating layer 113 as an example. However, in some other embodiments that do not carry out the widening step shown in FIG. 2G, the person of ordinary skill in the art should know that the widened first opening 131a can be replaced by the first opening 131, the widened second opening 133b can be replaced by the second opening 133, and the widened third opening 135a can be replaced by the third opening 135. The width of the widened third opening 135a is smaller than the widened first opening 131a and the widened second opening 133a.

Next, refer to FIGS. 2H and 2I, an isolation layer 143 is formed in the widened first opening 131a, the widened second opening 133a, and the widened third opening 135a. In some embodiments, as shown in FIG. 2H, a first liner 140a is conformally formed on the surfaces of the widened first opening 131a, the widened second opening 133a, and the widened third opening 135a. In some embodiments, the first liner 140a includes silicon nitride or another suitable insulating material and is formed by a deposition process with high gap-fill capability, such as an atomic layer deposition process.

After the first liner 140a is formed, a second liner 140b is formed on the first liner 140a to cap (sealing) the top of the widened third opening 135a, so that the widened third opening 135a has an air gap 142 surrounded by the first liner 140a and the second liner 140a and extending along the first direction. As explained earlier, the air gap 142 helps to reduce the parasitic capacitance between adjacent storage capacitor contacts that are subsequently formed. The second liner 140b is also conformally formed on the first liner 140a in the widened first opening 131a and the widened second opening 133a. That is, the second liner 140b does not make the widened first opening 131a and the widened second opening 133a be sealed.

In some embodiments, the second liner 140b includes a material that is the same as or different from the material of the first liner 140a. For example, the second liner 140b may include silicon nitride or another suitable insulating material, and may be formed by, a low-pressure chemical vapor deposition (LPCVD) process or another deposition process suitable for sealing.

Next, as shown in FIG. 2I, the excess second liner 140b and the excess underlying first liner 140a are removed to form an inverted U-shaped isolation layer 143 (as shown in FIG. 4) in the widened third opening 135a, and a first insulating spacer 141a and a second insulating spacer 141b are also formed on sidewalls of the widened first opening 131a and the widened second opening 133a. In other words, the first insulating spacer 141a, the second insulating spacer 141b and the isolation layer 143 are made of the same material. In some embodiments, an etch-back process is performed on the second liner 140b and the underlying first liner 140a to remove the horizontally extending portions of the first liner 140a and the second liner 140b, so that the top surfaces of first active area 100a, the second active area 100b and the insulating layer 113 are exposed. This etch back process may be an anisotropic etch process.

In some embodiments, after performing the anisotropic etching process, the lower portion of the first insulating spacer 141a and the lower portion of the second insulating spacer 141b have a thinner thickness than the upper portion thereof. Based on this, in the subsequent processes, the lower portion of the first insulating spacer 141a and the lower portion of the second insulating spacer 141b are prone to be damaged (e.g., due to the etchant), so that the subsequently formed storage capacitor contacts may laterally extend into the insulating layer 113 easily. Even so, the formed isolation layer 143 according to present disclosure can obstruct the lateral extension of adjacent storage capacitor contacts from bridging.

Afterwards, refer to FIG. 1B together, a first storage capacitor contact 150a is formed in the widened first opening 131a, and a second storage capacitor contact 150b is formed in the widened second opening 133a. As a result, the first insulating spacer 141a is formed between the first storage capacitor contact 150a and the insulating layer 113, and the second insulating spacer 141b is formed between the second storage capacitor contact 150b and the insulating layer 113. In addition, in some embodiments that are not shown, capacitor structures are formed on the first storage capacitor contact 150a and the second storage capacitor contact 150b, and then other well-known techniques can be used to accomplish a DRAM.

In some other embodiments, as shown in FIG. 2I-1, after the first liner 140a and the second liner 140b are formed, an etch-back process (e.g., isotropic etching process) is performed to remove the second liner 140b and the first liner 140a on the top surface of the insulating layer 113 and in the widened first opening 131a and the widened second opening 133a. After the isotropic etching process is performed, the isolation layer 143 is only formed in the widened third opening 135a, and the inner surfaces of the widened first opening 131a and the widened second opening 133a are exposed. As a result, the subsequently formed first storage capacitor contact 150a and second storage capacitor contact 150b are in direct contact with the sidewall surfaces of the insulating layer 113, and their volume can be increased. As a result, the contact resistances of the first storage capacitor contact 150a and the second storage capacitor contact 150b are reduced.

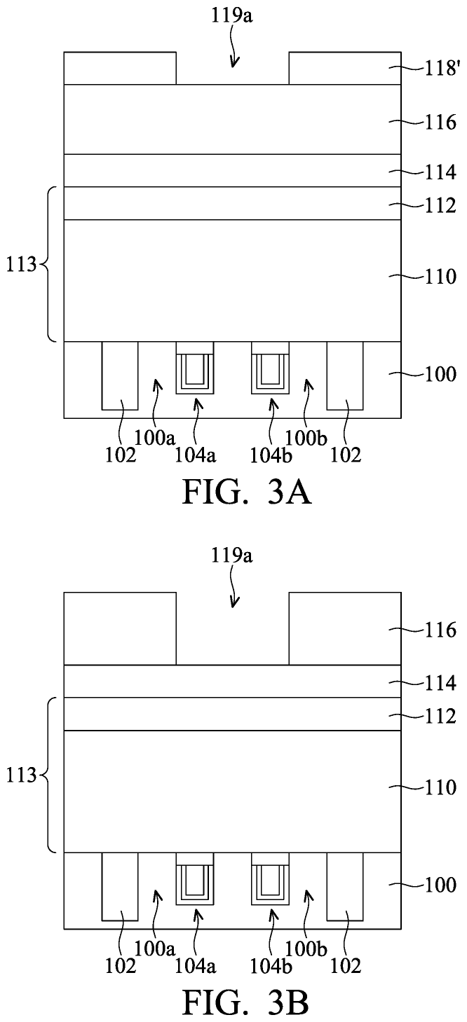

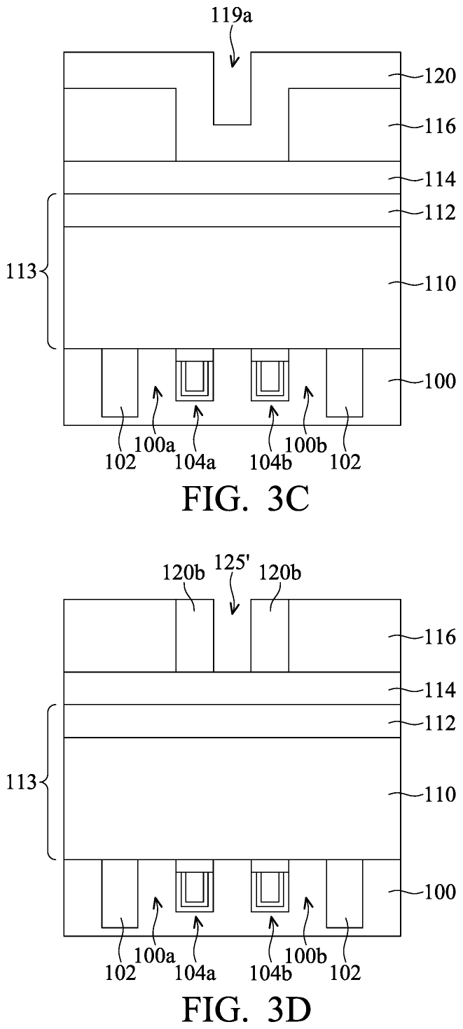

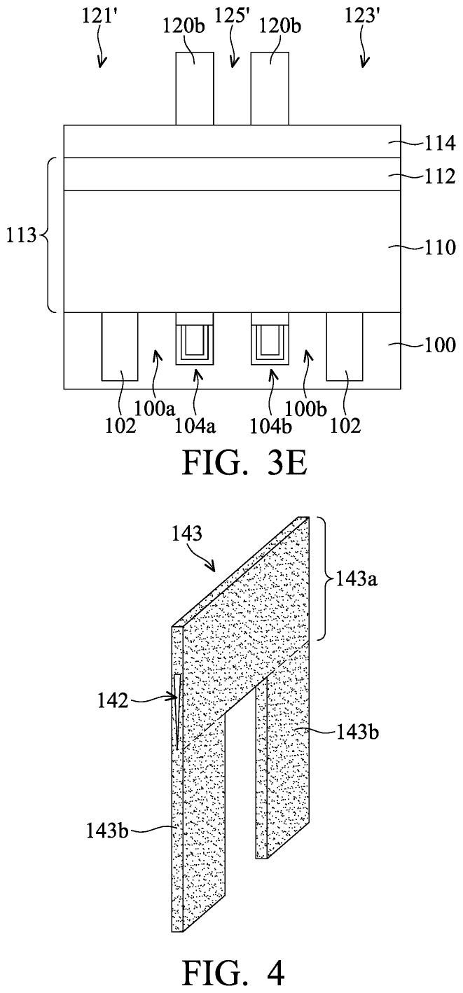

Refer to FIGS. 3A-3E, which illustrate cross-sectional views of various intermediate fabrication stages of semiconductor structures according to some other embodiments of the present disclosure. Herein, elements that are the same as those in the semiconductor structures shown in FIGS. 2A-2H are labeled with the same reference numbers as in FIGS. 2A-2H and are not described again. Unlike the photoresist pattern layer 118 having a mandrel pattern shown in FIG. 2A, a photoresist pattern layer 118′ shown in FIG. 3A has an opening pattern 119a. As viewed in a top-view perspective, the opening pattern 119a extends along the first direction.

Next, refer to FIG. 3B, the sacrificial layer 116 is patterned to transfer the opening pattern 119a of the photoresist pattern layer 118′ into the underlying sacrificial layer 116. As a result, the sacrificial layer 116 having the opening pattern 119a is formed on the hard mask layer 114.

Next, refer to FIG. 3C, the spacer material liner 120 is formed on the hard mask layer 114 to conformally cover the top surface of the sacrificial layer 116 and the sidewall surfaces and the lower surface of the opening pattern 119a.

Next, refer to FIG. 3D, the horizontally extending portion of the spacer material liner 120 is removed to leave the spacer layer 120b that covers the sidewall surfaces of the opening pattern 119a. In one embodiment, an anisotropic etching process is performed on the spacer material liner 120 to remove the horizontally extending portion of the spacer material liner 120. The formed spacer layer 120b has a mandrel-opening pattern 125′. The mandrel-opening pattern 125′ is employed to define the region where the subsequent isolation layer is to be formed.

Next, refer to FIG. 3E, the sacrificial layer 116 is removed to form opening patterns 121′ and 123′. The opening patterns 121′ and 123′ are separated from the mandrel-opening pattern 125′ by the spacer layer 120b. The opening patterns 121′ and 123′ are employed to define the region where the subsequent storage capacitor contacts are to be formed.

Next, in some embodiments, the method shown in FIG. 2F is performed to transfer the opening patterns 121′ and 123′ and the mandrel-opening pattern 125′ into the insulating layer 113 to form a first opening 131, a second opening 133, and a third opening 135. Next, in some embodiments, the method shown in FIG. 2G to FIG. 2I or 2I-1 can be performed to form the first storage capacitor contact on the widened first opening 131a (or the first opening 131) and form a second storage capacitor contact in the widened second opening 133a (or second opening 133). According to the foregoing embodiments, by forming an inverted U-shaped isolation layer in the insulating layer between two adjacent storage capacitor contacts, the inverted U-shaped isolation layer can span the bit line and obstruct the lateral extension of the adjacent storage capacitor contacts from bridging. As a result, electrical isolation between storage capacitor contacts can be ensured.

According to the foregoing embodiments, by additionally forming an inverted U-shaped isolation layer in the insulating layer between two adjacent storage capacitor contacts, the thickness of the spacer layer between the insulating layer and the storage capacitor contact can be reduced or the spacer layer can be omitted. As a result, the volume of the storage capacitor contact can be increased, thereby reducing the contact resistance of the storage capacitor contact.

According to the above-mentioned embodiment, by forming an air gap in the inverted U-shaped isolation layer, the dielectric constant of the electrical isolation layer between two adjacent storage capacitor contacts can be reduced, thereby reducing the parasitic capacitance between the two adjacent storage capacitor contacts.

The present invention is suitable for making miniaturized semiconductor devices, for example DRAMs, so as to increase the total number of dies on a wafer. Therefore, the production cost and energy consumption of manufacturing a single IC are reduced, and the production energy consumption of subsequent packaging is also reduced, thereby reducing carbon emissions in the process of producing the semiconductor devices. Besides, due to reducing the contact resistance of the storage capacitor contact, and reducing the parasitic capacitance between the two adjacent storage capacitor contacts, the present disclosure can improve the sense margin, thereby reducing power consumption and increasing operating speed, so as to be suitable for use in low power products. Therefore, the present disclosure provides a sustainable semiconductor device.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate having a first active area and an adjacent second active area;
a first word line and a second word line, disposed in the substrate;
a bit line spanning the first word line and the second word line;
a first storage capacitor contact and a second storage capacitor contact, formed on the first word line and the second word line, respectively, to be coupled to the first active area and the second active area, respectively, wherein the first storage capacitor contact and the second storage capacitor contact are disposed on the same side of the bit line;
an insulating layer disposed between the first storage capacitor contact and the second storage capacitor contact; and
an inverted U-shaped isolation layer disposed in the insulating layer and spanning the bit line.

2. The semiconductor structure as claimed in claim 1, wherein the inverted U-shaped isolation layer comprises a horizontal portion and two extending portions, and wherein the two extending portions extend from two ends of the horizontal portion in a direction toward the substrate.

3. The semiconductor structure as claimed in claim 2, wherein the horizontal portion of the inverted U-shaped isolation layer covers a top surface of the bit line, and wherein the extending portions of the inverted U-shaped isolation layer cover opposite sidewall surfaces of the bit line, respectively.

4. The semiconductor structure as claimed in claim 2, wherein the horizontal portion of the inverted U-shaped isolation layer extends in a direction same as the first word line and the second word line extend, as viewed from a top-view perspective.

5. The semiconductor structure as claimed in claim 4, wherein the horizontal portion of the inverted U-shaped isolation layer has an air gap, and wherein the air gap extends along the extending directions of the first word line and the second word line and spans the bit line.

6. The semiconductor structure as claimed in claim 1, wherein the inverted U-shaped isolation layer extends from a top surface of the insulating layer to a bottom surface of the insulating layer.

7. The semiconductor structure as claimed in claim 1, further comprising:
a first insulating spacer disposed between the first storage capacitor contact and the insulating layer; and
a second insulating spacer disposed between the second storage capacitor contact and the insulating layer.

8. The semiconductor structure as claimed in claim 7, wherein the first insulating spacer, the second insulating spacer and the inverted U-shaped isolation layer are made of a same material.

9. The semiconductor structure as claimed in claim 1, wherein the insulating layer comprises silicon oxide, and the inverted U-shaped spacer layer comprises silicon nitride.

10. The semiconductor structure as claimed in claim 1, wherein the first storage capacitor contact and the second storage capacitor contact each have an upper conductive structure and a lower conductive structure, and wherein the upper conductive structure comprises a metal, and the lower conductive structure comprises polysilicon.

11. A method of forming a semiconductor structure, comprising:
forming a first word line and a second word line that extend along a first direction and in a substrate, wherein the substrate has a first active area and an adjacent second active area;
forming an insulating layer on the substrate;
patterning the insulating layer to form a first opening, a second opening, and a third opening between the first opening and the second opening, wherein the first opening and the second opening correspond to the first active area and the second active area, respectively, and the third opening extends between the first word line and the second word line along the first direction, as viewed from a top-view perspective;
forming an isolation layer in the third opening; and
forming a first storage capacitor contact in the first opening and forming a second storage capacitor contact in the second opening.

12. The method as claimed in claim 11, wherein patterning the insulating layer further comprises:
successively forming a mask layer and a sacrificial layer on the insulating layer;
patterning the sacrificial layer to form a sacrificial mandrel layer;
forming a spacer layer on the mask layer, wherein the spacer layer has a first opening pattern and a second opening pattern that are disposed on two opposite sides of the sacrificial mandrel layer, respectively, and the first opening pattern and the second opening pattern are separated from the sacrificial mandrel layer by the spacer layer;
removing the sacrificial mandrel layer to form a third opening pattern in the spacer layer; and
successively etching the mask layer and the insulating layer to form the first opening pattern, the second opening pattern, and the third opening pattern transferred into the insulating layer to form the first opening, the second opening, and the third opening.

13. The method as claimed in claim 11, wherein patterning the insulating layer further comprises:
successively forming a mask layer and a sacrificial layer on the insulating layer;
patterning the sacrificial layer to form a first opening pattern;
forming a spacer layer to cover sidewall surfaces of the first opening pattern and form a mandrel opening pattern in the spacer layer;
removing the sacrificial layer, so that the spacer layer has a second opening pattern and a third opening pattern disposed on two opposite sides of the mandrel opening pattern, respectively, and the second opening pattern and the third opening pattern are separated from the mandrel opening pattern by the spacer layer; and
successively etching the mask layer and the insulating layer to transfer the second opening pattern, the third opening pattern, and the mandrel opening pattern into the insulating layer, so as to form the first opening, the second opening and the third opening, respectively.

14. The method as claimed in claim 11, wherein forming the isolation layer comprises:
conformally forming a first liner on a surface of the third opening; and
covering a top of the third opening with a second liner, so that the isolation layer has an air gap, wherein the air gap extends along the first direction.

15. The method as claimed in claim 14, wherein the first liner and the second liner are made of a same material and formed by different deposition processes.

16. The method as claimed in claim 14, wherein the first liner is formed on surfaces of the first opening and the second opening during the formation of the first liner, and the second liner is conformally formed on the first liner in the first opening and the second opening during the formation of the second liner.

17. The method as claimed in claim 16, further comprising:
removing the second liner and the first liner in the first opening and the second opening before forming the first storage capacitor contact and the second storage capacitor contact.

18. The method as claimed in claim 11, wherein the insulating layer comprises silicon oxide, and the isolation layer comprises silicon nitride.

19. The method as claimed in claim 11, wherein the first storage capacitor contact and the second storage capacitor contact each have an upper conductive structure and a lower conductive structure, and wherein the upper conductive structure comprises a metal, and the lower conductive structure comprises polysilicon.
